(19) United States
(12) Patent Application Publication
(10) Pub. No.: US 2024/0219845 A1
(43) Pub. Date: Jul. 4, 2024

(54) OVERLAY MEASUREMENT METHOD AND METHOD OF MANUFACTURING SEMICONDUCTOR DEVICE USING THE SAME

(71) Applicant: SAMSUNG ELECTRONICS CO., LTD., SUWON-SI (KR)

(72) Inventors: SEUNGHAK PARK, Suwon-si (KR); Jinsun Kim, Suwon-si (KR); Jeongjin Lee, Suwon-si (KR)

(21) Appl. No.: 18/460,679

(22) Filed: Sep. 4, 2023

(30) Foreign Application Priority Data
Jan. 4, 2023 (KR) 10-2023-0001328

(51) Int. Cl. G03F 7/00; H01L 21/66

(52) U.S. Cl. CPC G03F 7/70633; H01L 22/12

(57) ABSTRACT

An overlay measurement method includes providing a device structure including a substrate, a lower stack on the substrate and an upper stack on the lower stack, measuring a first overlay including critical dimension (CD) information of the device structure, measuring a second overlay including tilt information of the device structure, and calculating a compensation overlay by combining the first overlay and the second overlay, wherein the device structure has a first structure penetrating a portion of at least one of the lower stack or the upper stack in a vertical direction perpendicular to an upper surface of the substrate, and a second structure penetrating a portion of the lower stack and a portion of the upper stack in the vertical direction.

### CROSS-REFERENCE TO RELATED APPLICATION

This application is based on and claims priority under 35 U.S.C. § 119 to Korean Patent Application No. 10-2023-0001328, filed on Jan. 4, 2023, in the Korean Intellectual Property Office, the disclosure of which is incorporated by reference herein in its entirety.

### TECHNICAL FIELD

The inventive concept relates to an overlay measurement method and a method of manufacturing a semiconductor device using the overlay measurement method, and more particularly, to an overlay measurement method including in-cell overlay measurement and correction.

### DESCRIPTION OF RELATED ART

The measurement of device features may be useful in semiconductor device fabrication, particularly as design rules become smaller. Critical dimension and overlay measurements are typically taken during semiconductor device fabrication. Critical dimension measurements may be used ensure that a device satisfies a design rule. Overlay measurements may be used to ensure alignment of successive patterns and layers of the device.

Overlay measurement technology may be used to measure and control the alignment of a pattern used in manufacturing a semiconductor device. For example, overlay measurement technology may be used to measure and control an alignment between an upper stack and a lower stack. Alignment may be important as the design rules of semiconductor devices become smaller.

Conventional measurement methods using an overlay-only key in a scribe lane not accurately represent an overlay of a pattern in a cell according to a physical distance between patterns of an actual cell.

### SUMMARY

The inventive concept provides an overlay measurement method that may increase an accuracy of overlay measurement for a pattern included in a cell region, and a method of manufacturing a semiconductor device using the overlay measurement method.

According to an aspect of the inventive concept, an overlay measurement method includes providing a device structure including a substrate, a lower stack on the substrate and an upper stack on the lower stack, measuring a first overlay including critical dimension (CD) information of the device structure, measuring a second overlay including tilt information of the device structure, and calculating a compensation overlay by combining the first overlay and the second overlay, wherein the device structure has a first structure penetrating a portion of at least one of the lower stack or the upper stack in a vertical direction perpendicular to an upper surface of the substrate, and a second structure penetrating a portion of the lower stack and a portion of the upper stack in the vertical direction.

According to another aspect of the inventive concept, an overlay measurement method includes providing a device structure including a substrate, a lower stack on the substrate and an upper stack on the lower stack, measuring a first overlay including critical dimension (CD) information of the device structure, measuring a second overlay including tilt information of the device structure, and calculating a compensation overlay by combining the first overlay and the second overlay, wherein the device structure has a first structure penetrating a first portion of at least one of the lower stack or the upper stack in a vertical direction perpendicular to an upper surface of the substrate, and a second structure penetrating a second portion of the lower stack and a second portion of the upper stack in the vertical direction, and the second overlay includes tilt information of each of the first structure and the second structure, and tilt information of the first structure with respect to the second structure.

According to another aspect of the inventive concept, a method of manufacturing a semiconductor device includes stacking, in a vertical direction, a plurality of stacks on a cell region of a substrate, each stack of the plurality of stacks including at least one channel hole extending in a vertical direction perpendicular to an upper surface of the substrate, forming at least one word line cut penetrating at least two of the plurality of stacks in the vertical direction, measuring a first overlay including critical dimension information of each of the at least one channel hole and the at least one word line cut at an interface of each of the plurality of stacks, measuring a second overlay including tilt information of each of the at least one channel hole and the at least one word line cut at the interface of each of the plurality of stacks, calculating a compensation overlay by combining the first overlay with the second overlay, and compensating for positions of the at least one channel hole and the at least one word line cut using the compensation overlay, wherein the measuring of the second overlay includes tilt information of the at least one channel hole with respect to the at least one word line cut.

### BRIEF DESCRIPTION OF THE DRAWINGS

Embodiments will be more clearly understood from the following detailed description taken in conjunction with the accompanying drawings in which:

FIG. 1 illustrates a first overlay measurement system according to an embodiment;

FIG. 2 illustrates a second overlay measurement system according to an embodiment;

FIG. 3 is a flowchart illustrating an overlay measurement method according to an embodiment;

FIG. 4 is a schematic view illustrating a substrate used in an overlay measurement method according to an embodiment;

FIG. 5 is an enlarged view of a portion A of FIG. 4;

FIG. 6 is an overlay vector diagram illustrating the effects of an overlay measurement method according to an embodiment;

FIG. 7 is an overlay vector diagram using an overlay measurement method on upper and lower surfaces of a word line cut, according to an embodiment;

FIG. 8A, FIG. 8B, FIG. 8C, and FIG. 8D are cross-sectional views illustrating relative arrangements of channel holes and word line cuts;

FIG. 9 is a graph illustrating a process window according to a radius of a substrate, according to a comparative example;

FIG. 10 is a graph illustrating a process window according to a radius of a substrate, according to an embodiment; and

FIG. 11A, FIG. 11B, FIG. 12A, FIG. 12B, FIG. 13A, FIG. 13B, FIG. 14A, FIG. 14B, FIG. 15A and FIG. 15B are views illustrating a method of manufacturing a semiconductor device, according to embodiments.

### DETAILED DESCRIPTION

Hereinafter, embodiments are described in detail with reference to the accompanying drawings. The same reference numerals are used for the same components in the drawings, and duplicate descriptions thereof may be omitted.

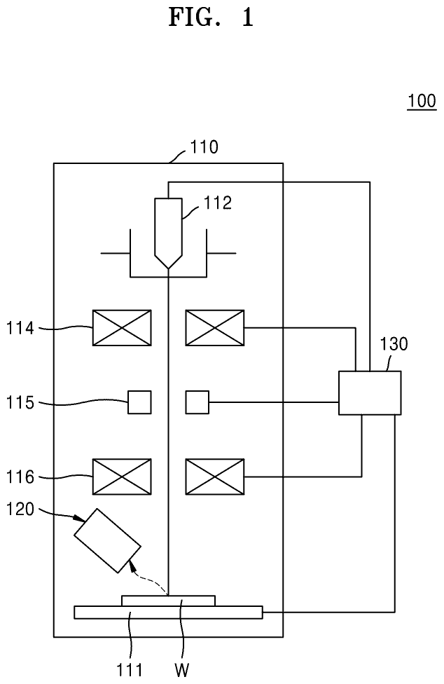

FIG. 1 illustrates a first overlay measurement system according to an embodiment.

Referring to FIG. 1, a first overlay measurement system 100 may include an electrooptical system 110. The electrooptical system 110 may apply an electron beam onto a substrate, such as a semiconductor substrate on which a multilayer structure is formed, and may detect emitted electrons. is the first overlay measurement system 100 may include a first processor 130 that may acquire and analyze an image from the electrons detected by the electrooptical system 110. The first processor 130 may calculate an overlay between an upper layer and a lower layer of the multilayer structure.

In embodiments, the first overlay measurement system 100 may measure an overlay between structures respectively penetrating a first layer and a second layer in a semiconductor manufacturing process for manufacturing semiconductor devices, such as dynamic random access memory (DRAM) or vertical NAND (VNAND) memory. For example, the first overlay measurement system 100 may measure an overlay of a substrate W by using a destructive inspection method. Herein, measuring an overlay may mean measuring an overlay offset.

As illustrated in FIG. 1, the electrooptical system 110 of the first overlay measurement system 100 may include a scanning electrooptical system. The scanning electrooptical system may include a scanning electron microscope (SEM) for imaging the substrate W having a plurality of layers. Specifically, the electrooptical system 110 may be a high-acceleration scanning electrooptical system. The electrooptical system 110 may include a microscope stage 111, an electron gun 112, a focusing lens 114, a deflector 115, an objective lens 116, and a first detector 120. The microscope stage 111 may support the substrate W. The electron gun 112 may generate a primary electron beam and control the direction and width of the primary electron beam. The focusing lens 114 may control the direction and width of the primary electron beam and apply the primary electron beam onto the substrate W. The first detector 120 may detect a detection signal, such as electrons emitted from the substrate W.

The first processor 130 may control an operation of the first overlay measurement system 100. The first processor 130 may control all operations of the first overlay measurement system 100. The first processor 130 may execute an operating system, applications, and so on. The first processor 130 may perform a function of a central processing unit (CPU).

Although FIG. 1 illustrates that the first overlay measurement system 100 includes a scanning electrooptical system, the inventive concept is not limited thereto. For example, the first overlay measurement system 100 may include a transmission electron microscope (TEM) and/or an ion milling device.

For example, the first overlay measurement system 100 may acquire an actual image representing a pattern, such as a channel hole with a high aspect ratio, a contact hole, or a word line cut, and a substructure of the pattern. For example, the first overlay measurement system 100 may acquire critical dimension (CD) information of each of the channel hole, the contact hole, and the word line cut.

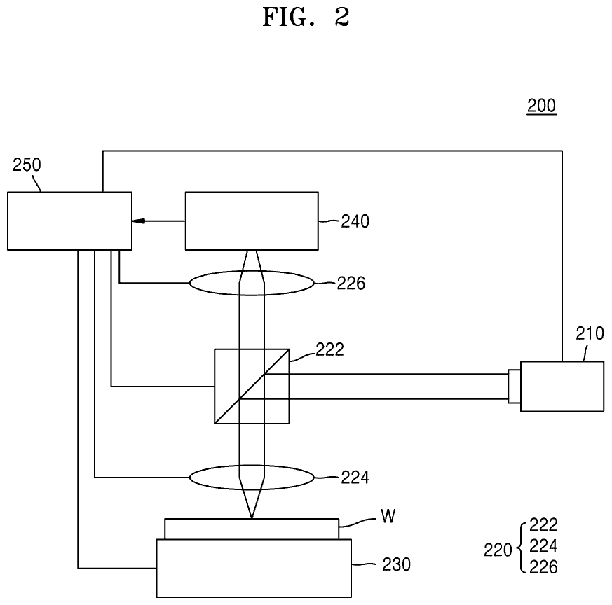

FIG. 2 illustrates a second overlay measurement system according to an embodiment.

Referring to FIG. 2, a second overlay measurement system 200 may include a diffraction-based overlay measurement device. For example, the second overlay measurement system 200 may perform an optical diffraction method. The second overlay measurement system 200 may be used to measure an overlay between an upper layer and a lower layer of a multilayer structure by applying light onto a cell region of a substrate W, such as a semiconductor substrate on which the multilayer structure is formed, and by acquiring and analyzing diffracted light and reflected light. For example, the second overlay measurement system 200 may measure the overlay as a function of a non-overlap or misalignment of layers. Measuring the overlay in the non-overlap manner is described herein with reference to FIG. 14A. In embodiments, the second overlay measurement system 200 may measure an overlay between structures respectively penetrating a first layer and a second layer in a non-destructive method in a semiconductor manufacturing process for manufacturing semiconductor devices, such as DRAM and VNAND memory.

The second overlay measurement system 200 may include a light source 210, an optical system 220, a stage 230, a second detector 240, and a second processor 250.

The light source 210 may generate and output light. The light source 210 may output light to the optical system 220. The light source 210 may generate and output light of various wavelengths. For example, the light source 210 may generate and output light having a wavelength between about 400 nm and about 900 nm. For example, the light source 210 may generate and output light of a wavelength in a visible light band.

The optical system 220 may transfer light received from the light source 210 to the substrate W. For example, the optical system 220 may include a beam splitter 222, a first lens 224, and a second lens 226. The beam splitter 222 may transfer light emitted from the light source 210 to the first lens 224. In addition, the light transferred from the first lens 224 may be incident on the second lens 226. The first lens 224 may transmit the light incident from the beam splitter 222 to the substrate W. Also, the light reflected and/or diffracted from the substrate W may be incident on the beam splitter 222. The second lens 226 may transfer the light incident from the beam splitter 222 to the second detector 240. In an embodiment, the first lens 224 and the second lens 226 may each include an objective lens. In some embodiments, the first lens 224 and/or the second lens 226 may be omitted.

The substrate W may be on the stage 230. The stage 230 may support and fix the substrate W in place. The stage 230 may support a bottom surface or a side surface of the substrate W to fix the substrate W in place. The stage 230 may be a movable stage. For example, the stage 230 may be a three-dimensional (3D) movable stage. As the stage 230 moves, the substrate W may also move with the stage 230. For example, the stage 230 may be moved in a Z axis to change a focus of the light incident from the first lens 224, or may be scanned on an X-Y plane to change an area receiving the light. These and other movements of the stage 230 may be performed to move the substrate W fixed to the stage 230.

The second detector 240 may detect the reflected light and diffracted light from the substrate W. For example, some of the light incident on the substrate W may be diffracted and/or reflected by the substrate W. For example, the second detector 240 may detect zero-order diffraction light.

The second processor 250 may control an operation of the second overlay measurement system 200. The second processor 250 may control all operations of the second overlay measurement system 200. The second processor 250 may be substantially similar to the first processor 130.

For example, the second overlay measurement system 200 may acquire information representing a pattern, such as a channel hole with a high aspect ratio, a contact hole, or a word line cut, and a structure of the pattern. For example, the second overlay measurement system 200 may acquire tilt information of a channel hole and tilt information of each word line cut. For example, the tilt information may include tilt direction information and tilt magnitude information.

For example, the second overlay measurement system 200 may measure a vertical distribution of each of the channel hole and the word line cut. For example, the vertical distribution of each of the channel hole and the word line cut may indicate a misalignment of upper and lower surfaces of each of the channel hole and the word line cut, which may be caused by a tilt. Deviations from an intended tilt (e.g., 0 degrees) may cause asymmetric overlap errors in layers of a semiconductor device, where tilt may refer to an angle of the wafer relative to an ion beam.

According to embodiments, the second overlay measurement system 200 may measure an overlay of a pattern formed on a cell region of the substrate W in a non-destructive method. The second overlay measurement system 200 may measure and compensate for the overlay at a relatively high measurement speed. In another embodiment, the second overlay measurement system 200 may measure an overlay in a destructive inspection method.

In view of the foregoing, the first overlay measurement system 100 and the second overlay measurement system 200 may be different processes for measuring the first overlay and the second overlay, respectively.

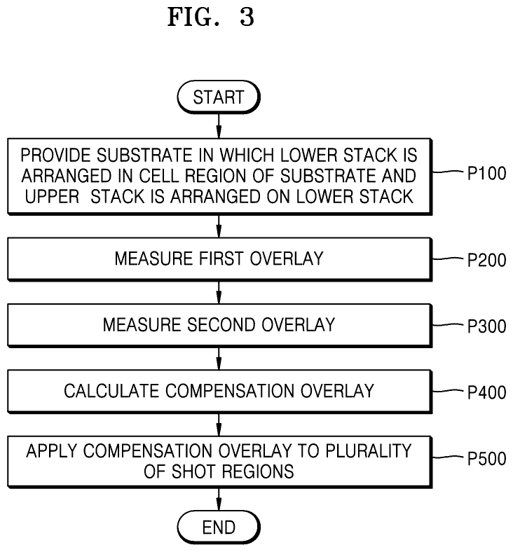

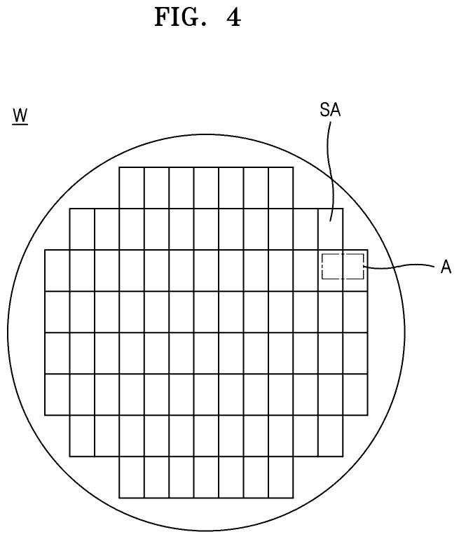

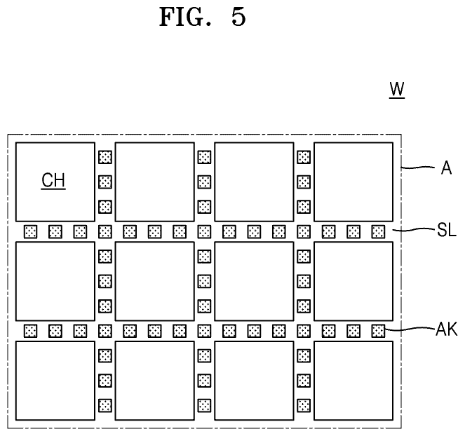

FIG. 3 is a flowchart illustrating an overlay measurement method according to an embodiment. FIG. 4 is a schematic view illustrating the substrate W used in an overlay measurement method according to an embodiment, and FIG. 5 is an enlarged view of a portion A of FIG. 4. Descriptions are given with reference to FIG. 1 and FIG. 2, and the repetitive descriptions may be omitted or briefly given.

Referring to FIG. 3, FIG. 4, and FIG. 5, a device structure may be provided that may include the substrate W, a lower stack on the substrate W in a cell region of the substrate W, and an upper stack on the lower stack (P100).

The substrate W may include semiconductor devices, such as DRAM and VNAND memory. Alignment keys AK for measuring alignment of the substrate W or multi-pattern layers may be formed on the substrate W. For example, the alignment keys AK may be marks on the substrate W, and the alignment keys AK may be used for matching an overlay or determining an alignment of the substrate W during a first process and a second process subsequent to the first process in a semiconductor device manufacturing process. The alignment keys AK may be used for various steps in a semiconductor device manufacturing process. For example, the alignment keys AK may be used to measure a position of the substrate W at one or more steps or exposure processes, including before a first exposure process for forming a first material pattern on the substrate W is performed, after the first exposure process is performed, after an etching process for forming the first material pattern is performed, before a second exposure process for forming a second material pattern on the first material pattern is performed, after the second exposure process is performed, after an etching process for forming a second material pattern is performed, before a third exposure process for forming a third material pattern is performed, or after the third exposure process is performed.

The substrate W may include a plurality of shot regions SA, and each of the plurality of shot regions SA may be a region exposed by a single exposure process. For example, when the substrate W includes one hundred shot regions SA, the exposure process may be performed on the substrate W one hundred times.

Each of the plurality of shot regions SA may include a plurality of chip regions CH, and scribe lanes SL may be between the plurality of chip regions CH. A plurality of alignment keys AK may be disposed in the scribe lanes SL. For example, the plurality of alignment keys AK may be separated from each other at preset intervals in the scribe lane SL.

A cell region of the plurality of chip regions CH may refer to a region in which actual electronic components or actual patterns are formed. For example, the cell region may be a region that is separated from the scribe lane SL and does not include an alignment key of the alignment keys AK. A target pattern of interest in overlay measurement, for example, a channel hole, a contact hole, and/or a word line cut, may be disposed in the cell region.

In embodiments, the substrate W may include a lower stack formed on the cell region. For example, the lower stack may include a lower channel hole formed to penetrate the lower stack on the substrate. For example, the lower channel hole may have a circular horizontal cross-sectional shape. In embodiments, the upper stack may be formed on the lower stack, and the upper stack may include an upper channel hole formed to penetrate the upper stack. For example, the upper channel hole may have a circular horizontal cross-sectional shape and may be connected to the lower channel hole. Also, the substrate W may include a word line cut formed to penetrate at least a part of the upper stack and a part of the lower stack. For example, the word line cut may penetrate at least two stacks. The word line cut may have a circular horizontal cross-sectional shape.

In embodiments, each of the lower channel hole and the upper channel hole may have a vertical height between about 1 micrometer to about 20 micrometers. Each of the lower channel hole and the upper channel hole may have a relatively large aspect ratio, for example, a ratio of a vertical height of a hole to a width of a hole in a horizontal direction. Also, the word line cut may have a vertical height between about 2 micrometers and about 40 micrometers. The word line cut may have a relatively large aspect ratio.

In a case where the lower channel hole and the upper channel hole are in different stacks, an overlay of the lower channel hole and the upper channel hole may be measured. Also, because a process of forming a channel hole may be different from a process of forming a word line cut, an overlay of a channel hole and a word line cut may be additionally measured.

A first overlay of the substrate W may be measured by the first overlay measurement system 100 (P200). As described herein, the first overlay measurement system 100 may measure the first overlay of the substrate W by using a SEM. For example, the first overlay may include information on a critical dimension parameter on upper and lower surfaces of the lower channel hole, a critical dimension parameter on upper and lower surfaces of the upper channel hole, and/or a critical dimension parameter on upper and lower surfaces of the word line cut.

The first overlay measurement system 100 may measure the first overlay at a plurality of points. For example, when each of the lower stack and the upper stack includes a channel hole and a word line cut therein, the first overlay measurement system 100 may detect the first overlay on a lower surface of the lower stack, an upper surface of the lower stack, a lower surface of the upper stack, and an upper surface of the upper stack. For example, when channel holes and word line cuts are included in first, second, and third stacks, the first overlay measurement system 100 may detect the first overlay on lower and upper surfaces of the first stack, on lower and upper surfaces of the second stack, and on lower and upper surfaces of the third stack. For example, the first overlay measurement system 100 may measure the first overlay at an interface of each of a plurality of stacks. The interfaces of the plurality of stacks may include an upper surface and a lower surface of each of the plurality of stacks. For example, when a semiconductor device includes N (where N is a natural number) stacks, the first overlay measurement system 100 may measure the first overlay on 2N surfaces.

A second overlay of the substrate W may be measured by the second overlay measurement system 200 (P300). As described herein, the second overlay measurement system 200 may measure the second overlay of the substrate W by using a non-destructive inspection method. More generally, the second overlay measurement system 200 may measure the second overlay of a junction region of the upper stack 22 and the lower stack 12 between an upper first structure formed on the upper stack 22 and a lower first structure formed on the lower stack 12.

For example, the second overlay may include tilt information for each of a lower channel hole, an upper channel hole, and a word line cut. Also, the second overlay may include a difference between a tilt component of the word line cut and a tilt component of the channel hole. Also, the second overlay may include tilt information for the lower channel hole and the upper channel hole in an interface. Also, the second overlay may include tilt information for the lower channel hole and the upper channel hole in a junction region (JTP of FIG. 14B).

For example, while calculating the second overlay, when a tilt direction of the word line cut is different than a tilt direction of the channel hole at a certain point, the certain point may be classified as a weak point. Given knowledge of the weak point, an overlay of the weak point may be corrected. The overlay of the weak point may be corrected, while other points may not be changed. That is, the calculation of the compensation overlay may include assigning a weight value to the weak point that is greater than a weight value of a point other than the weak point. For example, the second overlay of the weak point may have a higher weight value than the second overlays of points other than the weak point.

In embodiments, the second overlay may be detected by using Zernike polynomial modeling. For example, an overlay of a second position of the upper stack, with respect to a first position of the lower stack, may include a radial tilt component. The radial tilt component may indicate a tendency of the upper stack to be misaligned from the first position of the lower stack to the second position having a radial tendency due to the radial tilt component of the substrate W. That is, the radial tilt component of the second position of the upper stack may indicate that an overlay of the second position different from a first position of the lower stack may have a tendency according to a certain function in the radial direction from a center of a substrate toward an edge of the substrate.

In embodiments, the substrate W may include a target pattern that may be misaligned due to tilting in the radial direction. For example, a second position of the upper channel hole at the center of the circular substrate W may be relatively aligned from a first position of the lower channel hole at the center of the substrate W, and a second position of the upper channel hole on an edge portion of the substrate W may be relatively misaligned from the first position of the lower channel hole on an edge portion of the substrate W.

Accordingly, overlay information detected at the center of the substrate W may be different from overlay information detected at the edge portion of the substrate W. In this way, an overlay error due to a tilt of a word line cut according to a radial position of the substrate W and an overlay error due to radial tilting between the lower channel hole and the upper channel hole may be measured, analyzed, and/or corrected.

Once the overlay error has been measured, a compensation overlay may be calculated (P400). The compensation overlay may be calculated by combining the first overlay with the second overlay. For example, the compensation overlay may be calculated by summing the first overlay and the second overlay.

The compensation overlay may be calculated, individually, for each vertical level of a semiconductor device. For example, the compensation overlay may be calculated for each interface of a semiconductor device. As described herein, the interface of the semiconductor device may indicate, for example, upper and lower surfaces of each of a plurality of stacks.

On the upper surface of the upper stack, the compensation overlay may be implemented by the first overlay. More particularly, on the upper surface of the upper stack, the compensation overlay may be implemented by the first overlay, and may not be affected by the second overlay. For example, on the upper surface of the upper stack, the first overlay may include a critical dimension on an upper surface of an upper channel hole and a critical dimension of a word line cut in an upper surface of the upper stack. For example, on the upper surface of the upper stack, the first overlay may include the critical dimension on the upper surface of the upper channel hole and a critical dimension of a word line cut in an upper surface of the word line cut.

Also, on a lower surface of the upper stack, the compensation overlay may be implemented by the first overlay and the second overlay in combination. For example, on the lower surface of the upper stack, the first overlay may include a critical dimension on a lower surface of an upper channel hole and a critical dimension of a word line cut in the lower surface of the upper stack.

For example, on the lower surface of the upper stack, the second overlay may include the vertical distribution of upper channel holes and the vertical distribution of the word line cuts. For example, on the lower surface of the upper stack, the vertical distribution of upper channel holes may indicate a misalignment of the upper channel hole caused by a tilt of the upper channel hole. Also, for example, on the lower surface of the upper stack, the vertical distribution of the word line cut may indicate a misalignment of the word line cut caused by a tilt of the word line cut. Also, for example, on the lower surface of the upper stack, the second overlay may include the difference between a tilt component of the word line cut and a tilt component of the upper channel hole.

Also, on an upper surface of the lower stack, the compensation overlay may be implemented by the first overlay and the second overlay in combination. On the upper surface of the lower stack, the first overlay may include a critical dimension on an upper surface of a lower channel hole and a critical dimension of a word line cut on the upper surface of the lower stack. On the upper surface of the lower stack, the second overlay may include the vertical distribution of the word line cuts. For example, on the upper surface of the lower stack, the second overlay may include the difference between a tilt component of the word line cut and a tilt component of a lower channel hole.

Also, on a lower surface of the lower stack, the compensation overlay may be implemented by the first overlay and the second overlay in combination. For example, on the lower surface of the lower stack, the first overlay may include a critical dimension on a lower surface of a lower channel hole and a critical dimension of a word line cut in the lower surface of the lower stack.

On the lower surface of the lower stack, the second overlay may include the vertical distribution of lower channel hole and the vertical distribution of the word line cut. For example, on the lower surface of the lower stack, the vertical distribution of the lower channel hole may indicate a misalignment of the lower channel hole caused by a tilt of the lower channel hole. Also, for example, on the lower surface of the lower stack, the vertical distribution of the word line cut may indicate a misalignment of the word line cut caused by a tilt of the word line cut. Also, on the lower surface of the lower stack, the second overlay may include the difference between a tilt component of the word line cut and a tilt component of the lower channel hole.

When the calculation of the compensation overlay for each interface is extended to a semiconductor device including a plurality of stacks, the compensation overlay includes the first overlay on an upper surface of the uppermost stack, and the compensation overlay includes the first overlay and the second overlay on other surfaces except for the upper surface of the uppermost stack.

The first overlay may include critical dimension information of each of a channel hole and a word line cut at each point. The second overlay may include the difference between a tilt component of the word line cut and a tilt component of the channel hole at each point. Also, on the upper surface of each of the plurality of stacks, the second overlay may include the vertical distribution of the word line cut and the vertical distribution of the channel hole at each point.

For example, applying the compensation overlay including the first overlay and the second overlay may be referred to as edge placement error (EPE) control.

Thereafter, the compensation overlay may be applied to one or more of the plurality of shot regions of the substrate W (P500). That is, formation positions of the lower channel hole, the upper channel hole, and the word line cut may be corrected by using a calculated compensation overlay. For example, the compensation overlay may be independently measured for each of the plurality of shot regions of the substrate W. That is, independent compensation overlays may be determined for each shot of a plurality of exposure processes performed on the substrate.

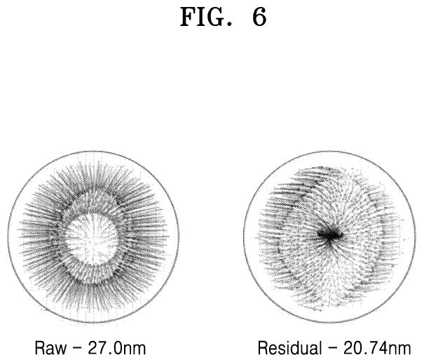

FIG. 6 is an overlay vector diagram illustrating effects of an overlay measurement method according to an embodiment. Descriptions are given with reference to FIG. 1 to FIG. 5.

Referring to FIG. 6, in an illustrative example, an average overlay offset of 27.0 nm is obtained in a step prior to overlay correction. After the compensation step is performed by using a modeling result, an average residual overlay offset of 20.74 nm is obtained. The modeling may be performed by using a circular coordinate system and/or a Zernike polynomial. Accordingly, effective overlay offset compensation may be made by using an overlay measurement method including a circular coordinate system and/or a Zernike polynomial.

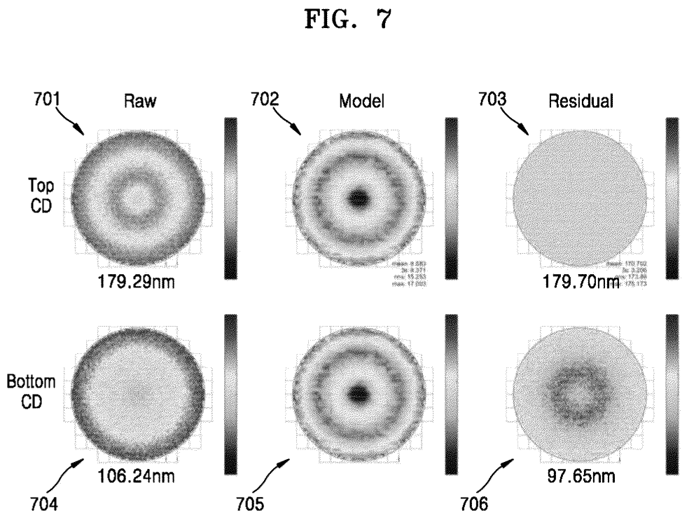

FIG. 7 is an overlay vector diagram using an overlay measurement method on upper and lower surfaces of a word line cut, according to an embodiment. In FIG. 7, three upper overlay vector diagrams 701, 702, 703, represent the overlay vector diagrams on an upper surface of a word line cut, and three lower overlay vector diagrams 704, 705, 706 represent overlay vector diagrams on a lower surface of the word line cut. Descriptions are given with reference to FIG. 1 to FIG. 6.

Referring to FIG. 7, in an illustrative example, on the upper surface of the word line cut, an average overlay offset of 179.29 nm is obtained at a step before overlay correction, and an average residual overlay offset of 170.70 nm is obtained after the compensation step is performed by using the modeling result. Also, on the lower surface of the word line cut, an average overlay offset of 106.24 nm is obtained at the step before the overlay correction, and an average residual overlay offset of 97.65 nm is obtained after the overlay correction. Accordingly, effective overlay offset compensation may be made by using the overlay measurement method. In addition, overlay measurement may be independently performed on the upper surface and the lower surface of the word line cut. That is, the overlay measurement may be independently performed at different points of a structure of a semiconductor device.

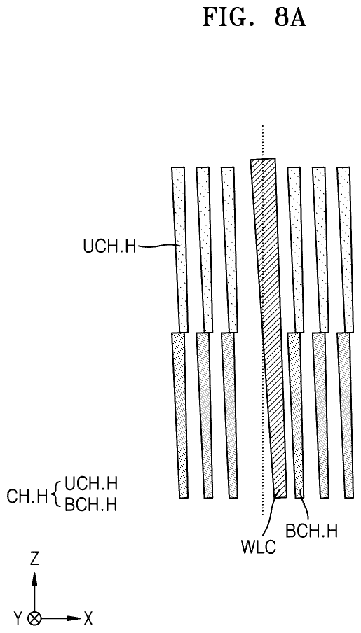

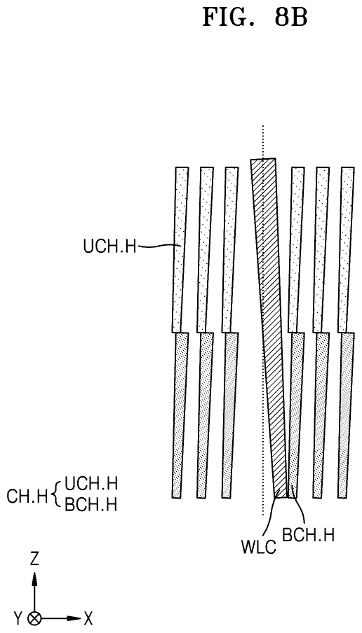

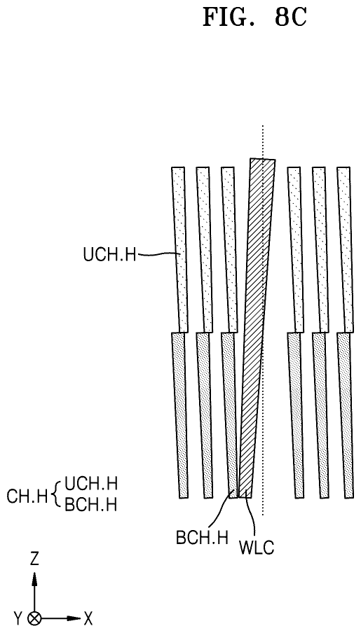

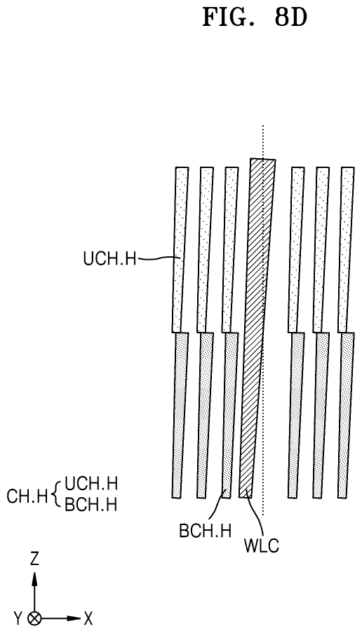

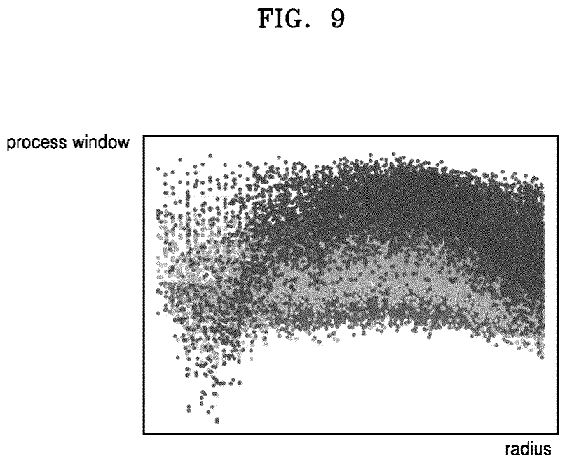

FIG. 8A, FIG. 8B, FIG. 8C, and FIG. 8D are cross-sectional views illustrating relative arrangements of channel holes and word line cuts. For the sake of convenience of description, only channel holes and word line cuts are illustrated as examples. Descriptions thereof are given with reference to FIG. 2, FIG. 3, FIG. 4, and FIG. 5. FIG. 8A, FIG. 8B, FIG. 8C, and FIG. 8D may illustratively show channel holes CH.H and word line cuts WLC formed in different parts of the substrate W. In FIG. 8A, FIG. 8B, FIG. 8C, and FIG. 8D, dashed lines are imaginary lines extending parallel to the vertical direction (the Z direction) with respect to the center of an upper surface of the word line cut WLC.

Referring to FIG. 8A, FIG. 8B, FIG. 8C, and FIG. 8D, upper channel holes UCH.H, lower channel holes BCH.H, and a word line cut WLC may extend in a vertical direction perpendicular to an upper surface of the substrate. Further, the upper channel holes UCH.H and the lower channel holes BCH.H may be tilted. The word line cut WLC may also be tilted. More particularly, while the upper channel holes UCH.H, the lower channel holes BCH.H, and the word line cut WLC may be described as extending in the vertical direction, these features may each have a tilt. Furthermore, the tilt of the channel holes CH.H may be different than a tilt of the word line cut WLC, for example. As described herein, tilt information of the channel holes CH.H and tilt information of the word line cut WLC may be measured by the second overlay measurement system 200 of FIG. 2.

In FIG. 8A and FIG. 8D, tilt directions of the channel holes CH.H are the same as a tilt direction of the word line cut WLC. Accordingly, overlay measurement may be performed by considering tilt magnitudes of the channel holes CH.H and a tilt magnitude of the word line cut WLC. In FIG. 8B and FIG. 8C, tilt directions of the channel holes CH.H are different from a tilt direction of the word line cut WLC. In this case, the overlay measurement may be performed by considering the tilt magnitudes and tilt directions of the channel holes CH.H and the tilt magnitude and tilt direction of the word line cut WLC. For example, FIG. 8B and FIG. 8C may be classified as including weak points. The weak point may be classified in a case where different features contact one another, for example, where a channel hole and a word line cut come into contact. In a case where the tilt directions of the channel holes CH.H are the same as the tilt direction of the word line cut WLC, as in FIG. 8A and FIG. 8D, a weak point may be identified by tilt magnitude alone, and consideration of tilt direction may be omitted in the identification of any weak point.

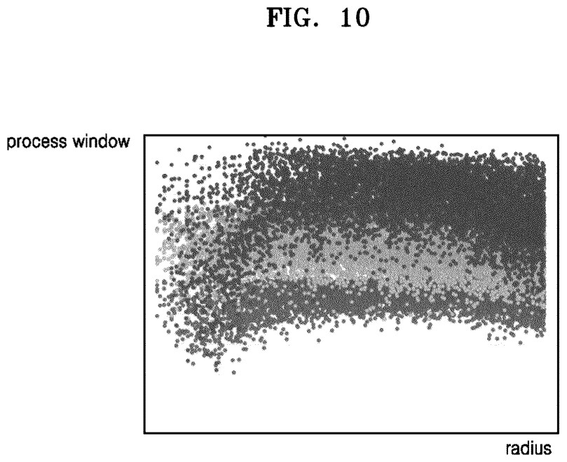

FIG. 9 is a graph illustrating a process window according to a radius of a substrate, according to a comparative example. FIG. 10 is a graph illustrating a process window according to a radius of a substrate, according to an embodiment. The process window may illustrate values of process parameters, in FIG. 9 and FIG. 10 as a function of the radius of the substrate, that may allow devices to be manufactured and to operate within desired specifications. In the graphs of FIG. 9 and FIG. 10, the horizontal axes each represent a radius from the center of the substrate W and the vertical axes each represent a process window. In the graphs of FIG. 9 and FIG. 10, the horizontal axes and the vertical axes represent certain units (a.u.).

Referring to FIG. 9, a process window according to the comparative example represents data when overlay correction is not made. Referring to FIG. 10, a process window according to an embodiment represents data after overlay correction including the first overlay and the second overlay is made. FIG. 10 illustrates an improvement in the data points within the process window according to an embodiment, where the data points may show improved grouping within the process window as compared to data points of the process window according to the comparative example. In view of the comparison of FIG. 9 and FIG. 10, overlay correction including the first overlay and the second overlay may effectively improve device qualities.

Here, the process window may indicate a combination of process parameters that affect manufacturing of a semiconductor device. For example, the process window may include critical dimension information and tilt information.

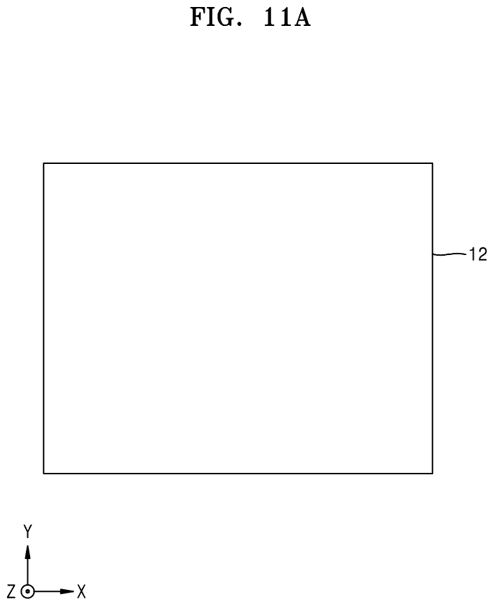

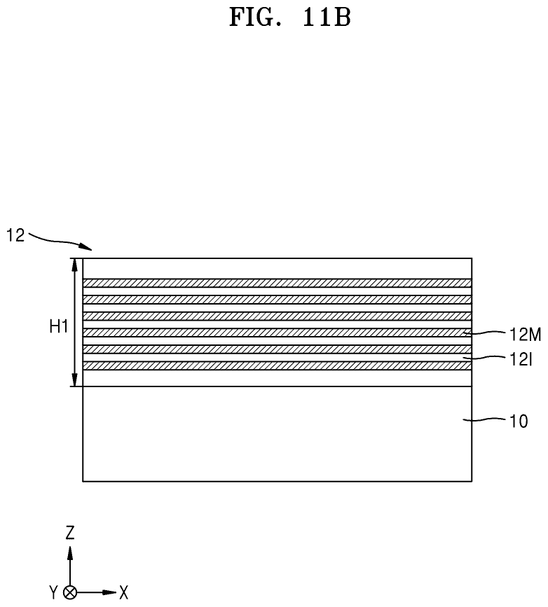

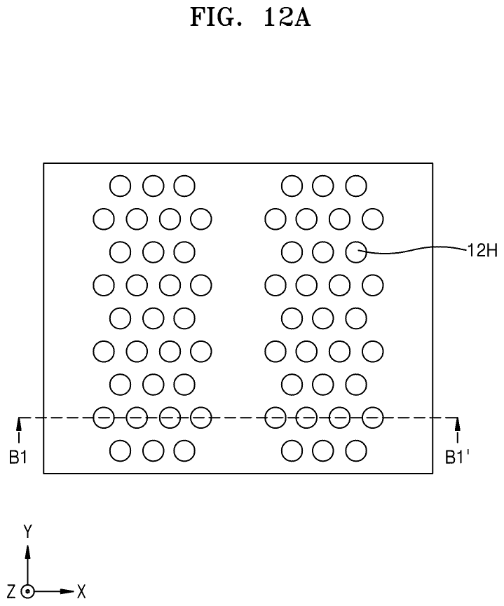

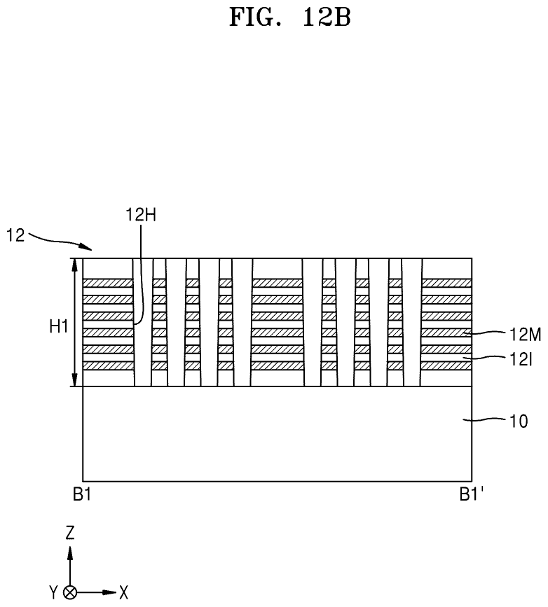

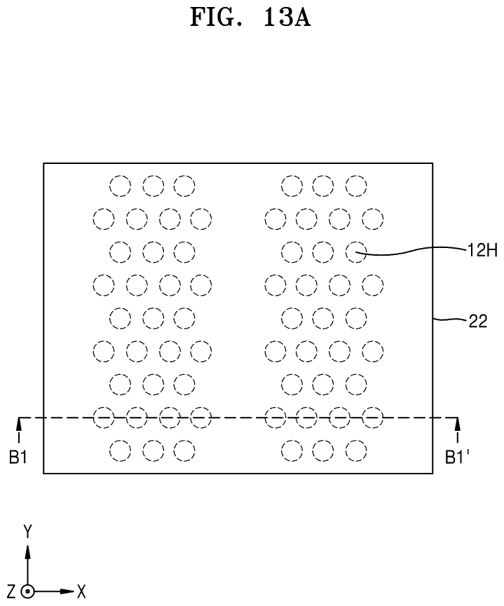

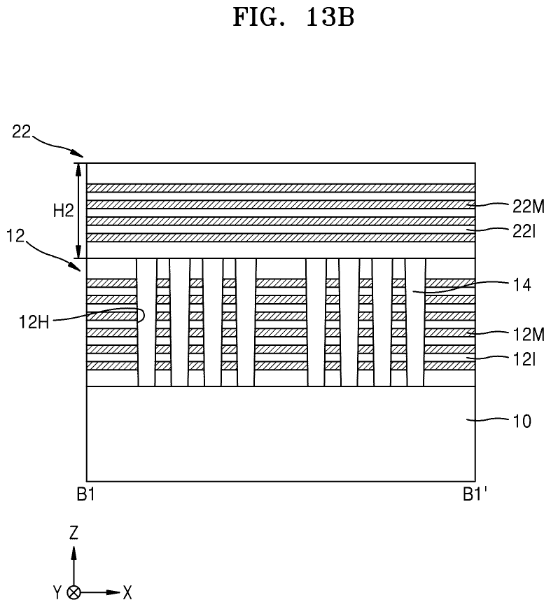

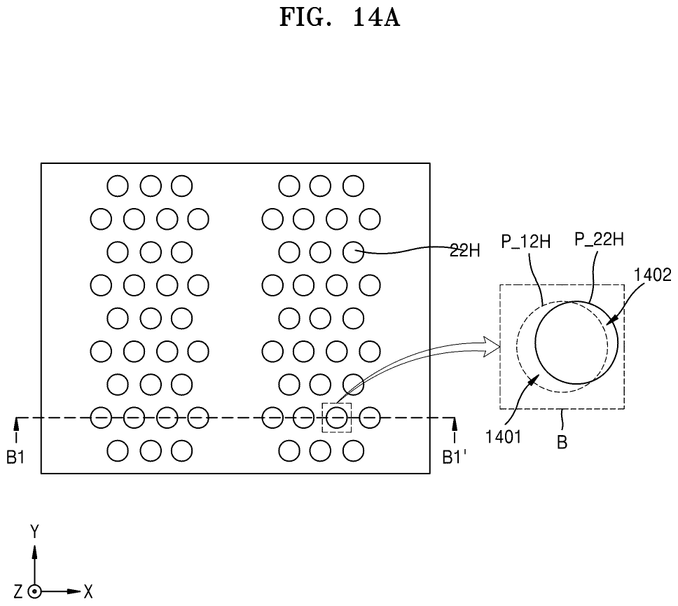

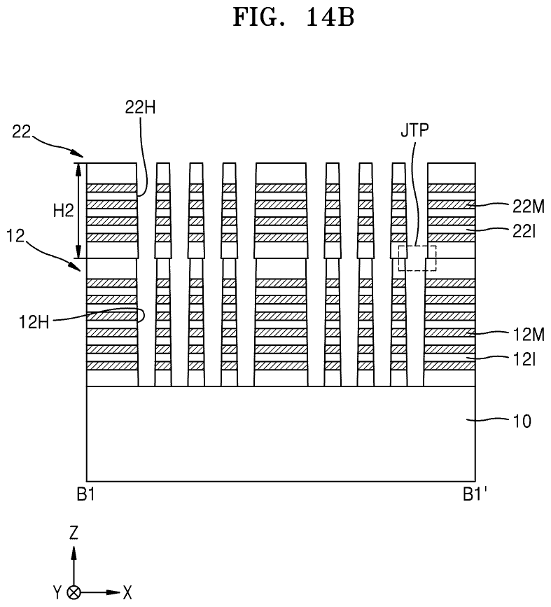

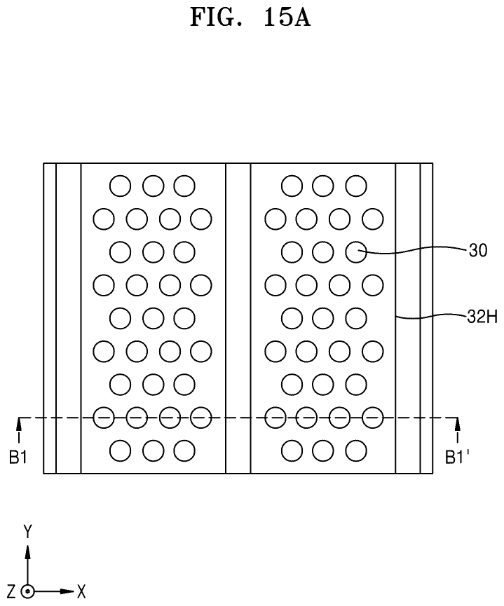

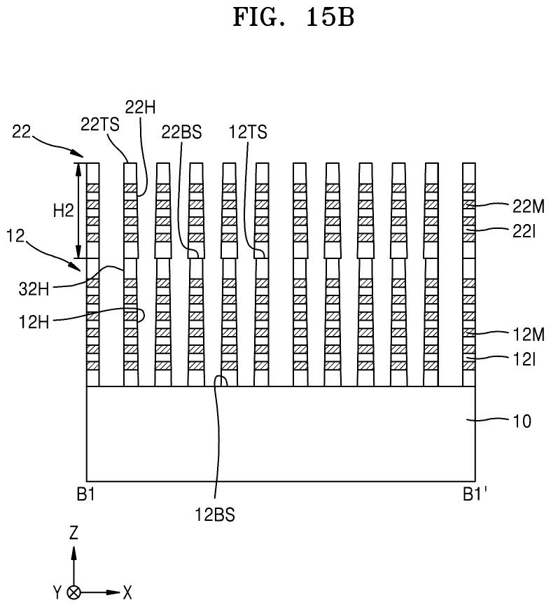

FIG. 11A to FIG. 15B are views illustrating a method of manufacturing a semiconductor device according to embodiments. FIG. 11A, FIG. 12A, FIG. 13A, FIG. 14A, and FIG. 15A are plan views illustrating the method of manufacturing the semiconductor device, and FIG. 11B, FIG. 12B, FIG. 13B, FIG. 14B, and FIG. 15B are cross-sectional views illustrating the method of manufacturing the semiconductor device. FIG. 11A to FIG. 15B illustrate a method of manufacturing a semiconductor device formed using an overlay measurement method described with reference to FIG. 3 according to an embodiment.

Referring to FIG. 11A and FIG. 11B, a lower stack 12 may be formed on a substrate 10. The lower stack 12 may include a plurality of mold layers 12M and a plurality of insulating layers 121. The plurality of mold layers 12M and the plurality of insulating layers 121 may be alternately arranged in the vertical direction (the Z direction). For example, a vertical height H1 of the lower stack 12 may be between about 1 micrometer to about 20 micrometers.

Referring to FIG. 12A and FIG. 12B, a photolithography patterning process may be performed on the lower stack 12. The photolithography patterning process may be performed on the lower stack 12 to form a mask pattern (not illustrated), and a part of the lower stack 12 may be removed by using the mask pattern as an etch mask to form a plurality of lower channel hole regions 12H.

The plurality of lower channel hole regions 12H may be arranged in a zigzag shape in a first horizontal direction (the X direction) and a second horizontal direction (the Y direction).

Thereafter, a protective layer 14 may be formed to fill the insides of the plurality of lower channel hole regions 12H (see FIG. 13B).

Referring to FIG. 13A and FIG. 13B, an upper stack 22 may be formed on the lower stack 12. The upper stack 22 may be formed on the lower stack 12 to cover the lower channel hole regions 12H. The upper stack 22 may include a plurality of mold layers 22M and a plurality of insulating layers 221. The plurality of mold layers 22M and the plurality of insulating layers 221 may be alternately arranged in the vertical direction (the Z direction). For example, a vertical height H2 of the upper stack 22 may be between about 1 micrometer to about 20 micrometers.

Referring to FIG. 14A and FIG. 14B, a photolithography patterning process may be performed on the upper stack 22. The photolithography patterning process may be performed on the upper stack 22 to form a mask pattern (not illustrated), and a part of the upper stack 22 may be removed by using the mask pattern as an etch mask to form a plurality of upper channel hole regions 22H.

The plurality of upper channel hole regions 22H may be arranged in a zigzag shape in the first horizontal direction (the X direction) and the second horizontal direction (the Y direction). The plurality of upper channel hole regions 22H may respectively vertically overlap the plurality of lower channel hole regions 12H (see FIG. 14A).

In some embodiments, a process of forming the plurality of upper channel hole regions 22H may include an ion beam etching process. As each of the plurality of upper channel hole regions 22H has a relatively large aspect ratio, an ion beam applied during the process of forming the plurality of upper channel hole regions 22H may have a radial tilt. The radial tilt of the ion beam may be larger at bottom portions P_22H of the plurality of upper channel hole regions 22H than at upper portions P_12H of the plurality of upper channel hole regions 22H. Accordingly, the bottom portions P_22H of the upper channel hole region 22H may be misaligned from the upper portions P_12H of the plurality of lower channel hole regions 12H. Accordingly, an overlay may be caused in a junction region JTP of the bottom portion of each of the plurality of upper channel hole regions 22H and an upper side of each of the plurality of lower channel hole regions 12H.

Tilt information of the junction region JTP may be measured based on misaligned areas of the bottom portions P_22H of the plurality of upper channel hole regions 22H and the upper portions P_12H of the plurality of lower channel hole regions 12H. For example, tilt information of the junction region JTP may be measured based on one or more non-overlap areas 1401 and 1402 of the bottom portions P_22H of the plurality of upper channel hole regions 22H and the upper portions P_12H of the plurality of lower channel hole regions 12H (see portion B of FIG. 14A).

Similarly, tilt information of the plurality of upper channel hole regions 22H may be measured based on non-overlap areas of upper sides of the plurality of upper channel hole regions 22H and the bottom portions P_22H of the plurality of upper channel hole regions 22H. In addition, tilt information of the plurality of lower channel hole regions 12H may be measured based on non-overlap areas of the upper portions P_12H of the plurality of lower channel hole regions 12H and bottom portions of the plurality of lower channel hole regions 12H.

Referring to FIG. 15A and FIG. 15B, word line cut regions 32H may be formed by removing a part of the upper stack 22 and a part of the lower stack 12. Compensation overlays may be respectively calculated on an upper surface 22TS of the upper stack 22, a lower surface 22BS of the upper stack 22, an upper surface 12TS of the lower stack 12, and a lower surface 12BS of the lower stack 12. As described herein, the compensation overlay on the upper surface 22TS of the upper stack 22 may be implemented by a first overlay, and the compensation overlay on each of the lower surface 22BS of the upper stack 22, the upper surface 12TS of the lower stack 12, and the lower surfaces 12BS of the lower stack 12 may be implemented by the first overlay and a second overlay. The compensation overlay on the upper surface 22TS of the upper stack 22 may not be affected by the second overlay.

As described herein, tilt information of the word line cut regions 32H may be measured based on misaligned areas of upper sides of the word line cut regions 32H and bottom portions of the word line cut regions 32H. For example, tilt information of the word line cut regions 32H may be measured based on non-overlap areas of upper sides of the word line cut regions 32H and bottom portions of the word line cut regions 32H.

Formation positions of lower channel holes, upper channel holes, and word line cuts of the device structure may be changed by using the calculated compensation overlay. A semiconductor device may be manufactured by performing the processes described herein.

In addition, although performing a method of measuring and compensating for overlays of channel holes and word line cuts is described as an example in embodiments described herein, the method of measuring and compensating for an overlay according to an embodiment may also be performed, in another embodiment, in a process of forming an opening with a large aspect ratio, such as forming a cell contact, a peripheral circuit contact, or a through-via.

Also, although performing the method of measuring and compensating the overlay is described as an example for a semiconductor device having a vertical channel structure, the method of measuring and compensating for an overlay according to an embodiment may also be performed, in another embodiment, in a process of forming an opening with a large aspect ratio in in a DRAM device, a phase-change random access memory (PRAM) device, a magnetic random access mem (MRAM) device, and so on, each including buried channel transistors.

While the inventive concept has been particularly shown and described with reference to embodiments thereof, it will be understood that various changes in form and details may be made therein without departing from the spirit and scope of the following claims.

What is claimed is:

1. An overlay measurement method comprising:
providing a device structure including a substrate, a lower stack on the substrate and an upper stack on the lower stack;
measuring a first overlay including critical dimension information of the device structure;
measuring a second overlay including tilt information of the device structure; and
calculating a compensation overlay by combining the first overlay and the second overlay,
wherein the device structure has a first structure penetrating a portion of at least one of the lower stack or the upper stack in a vertical direction perpendicular to an upper surface of the substrate, and a second structure penetrating a portion of the lower stack and a portion of the upper stack in the vertical direction.

2. The overlay measurement method of claim 1, wherein each of the first overlay and the second overlay is measured at different vertical levels of the device structure.

3. The overlay measurement method of claim 1, wherein each of the first overlay and the second overlay is measured on at least two of a lower surface of the lower stack, an upper surface of the lower stack, a lower surface of the upper stack, or an upper surface of the upper stack.

4. The overlay measurement method of claim 1, wherein the tilt information includes tilt direction information and tilt magnitude information of each of the first structure and the second structure.

5. The overlay measurement method of claim 1, wherein the first structure and the second structure are formed by different processes.

6. The overlay measurement method of claim 1, further comprising:
measuring the first overlay by a scanning electrooptical system; and
measuring the second overlay by an optical diffraction method.

7. An overlay measurement method comprising:
providing a device structure including a substrate, a lower stack on the substrate and an upper stack on the lower stack;
measuring a first overlay including critical dimension (CD) information of the device structure;
measuring a second overlay including tilt information of the device structure; and
calculating a compensation overlay by combining the first overlay and the second overlay,
wherein the device structure has a first structure penetrating a first portion of at least one of the lower stack or the upper stack in a vertical direction perpendicular to an upper surface of the substrate, and a second structure penetrating a second portion of the lower stack and a second portion of the upper stack in the vertical direction, and
the second overlay includes tilt information of each of the first structure and the second structure, and tilt information of the first structure with respect to the second structure.

8. The overlay measurement method of claim 7, wherein the second overlay is measured based on a misaligned area of an upper surface and a lower surface of each of the first structure and the second structure.

9. The overlay measurement method of claim 7, wherein
the compensation overlay includes the first overlay for an upper surface of the upper stack, and
the compensation overlay includes the first overlay and the second overlay for interfaces other than the upper surface of the upper stack.

10. The overlay measurement method of claim 7, wherein, on each of a lower surface of the lower stack and a lower surface of the upper stack, the second overlay includes a vertical distribution of each of the first structure and the second structure in each of the upper stack and the lower stack.

11. The overlay measurement method of claim 7, wherein the second overlay includes:
an overlay in a junction region of the upper stack and the lower stack between an upper first structure formed on the upper stack and a lower first structure formed on the lower stack, and
an offset of the overlay in the junction region includes a tilt component in a radial direction.

12. The overlay measurement method of claim 7, further comprising:
determining a tilt direction of the first structure;
determining a tilt direction of the second structure;
determining that the tilt direction of the first structure is different than the tilt direction of the second structure; and
identifying a weak point upon determining that the tilt direction of the first structure is different than the tilt direction of the second structure.

13. The overlay measurement method of claim 12, wherein the calculation of the compensation overlay further comprises assigning a weight value of the weak point that is greater than a weight value of a point other than the weak point.

14. The overlay measurement method of claim 7, further comprising measuring an overlay of a second position of the upper stack with respect to a first position of the lower stack using Zernike polynomial modeling.

15. The overlay measurement method of claim 7, wherein the tilt information includes a radial tilt component of the device structure.

16. The overlay measurement method of claim 7, wherein the first structure includes a channel hole, and the second structure includes a word line cut.

17. The overlay measurement method of claim 7, wherein the providing of the device structure comprises:
forming the lower stack on the substrate;
forming a lower channel hole extending in the vertical direction by removing the first portion of the lower stack;
forming the upper stack on the lower stack to cover the lower channel hole;
forming an upper channel hole extending in the vertical direction by removing the first portion the upper stack; and
forming a word line cut extending in the vertical direction by removing the second portion of the lower stack and the second portion of the upper stack.

18. A method of manufacturing a semiconductor device, the method comprising:
stacking, in a vertical direction, a plurality of stacks on a cell region of a substrate, each stack of the plurality of stacks including at least one channel hole extending in a vertical direction perpendicular to an upper surface of the substrate;
forming at least one word line cut penetrating at least two of the plurality of stacks in the vertical direction;
measuring a first overlay including critical dimension information of each of the at least one channel hole and the at least one word line cut at an interface of each of the plurality of stacks;
measuring a second overlay including tilt information of each of the at least one channel hole and the at least one word line cut at the interface of each of the plurality of stacks;
calculating a compensation overlay by combining the first overlay with the second overlay; and
compensating for positions of the at least one channel hole and the at least one word line cut using the compensation overlay,
wherein the measuring of the second overlay includes tilt information of the at least one channel hole with respect to the at least one word line cut.

19. The method of claim 18, wherein the compensating for the positions is made by independent compensation overlay for each shot of a plurality of exposure processes performed on the substrate.

20. The method of claim 18, wherein
the first overlay is measured by using a destructive inspection method, and
the second overlay is measured by using a non-destructive inspection method.
